(19) United States
(12) Patent Application Publication
(10) Pub. No.: US 2007/0172964 A1
(43) Pub. Date: Jul. 26, 2007

(54) METHOD OF FORMING SELF-ALIGNED CONTACT VIA FOR MAGNETIC RANDOM ACCESS MEMORY

(76) Inventors: Cheng-Tyng Yen, Kaohsiung City (TW); Wei-Chuan Chen, Taipei County (TW); Kuei-Hung Shen, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,903

(22) Filed: May 24, 2006

(30) Foreign Application Priority Data
Jan. 11, 2006 (TW) 95101043

(51) Int. Cl. H01L 21/00

(52) U.S. Cl. 438/3; 257/E21.665

(57) ABSTRACT

A method of forming a self-aligned contact via for a MRAM is disclosed. A first conductive layer, a pinned layer, a tunneling barrier layer, a free layer, a capping layer and a first dielectric layer are formed sequentially over a substrate has formed lots of transistors and interconects. A portion of the first dielectric layer and the capping layer are removed until a surface of the free layer is exposed. A portion of the pinned layer, the tunneling barrier layer and the free layer are removed to form a MRAM device. A second dielectric layer is formed over the magnetic random access memory device. A planarization process is performed to form a planar surface of the second dielectric layer. The first dielectric layer and a portion of the second dielectric layer are removed to form a self-aligned contact opening. A second conductive layer is filled into the self-aligned contact opening.

### CROSS-REFERENCE TO RELATED APPLICATION

This application claims the priority benefit of Taiwan application serial no. 95101043, filed on Jan. 11, 2006. All disclosure of the Taiwan application is incorporated herein by reference.

### BACKGROUND OF THE INVENTION

1. Field of the Invention

The present invention relates to a method of forming a contact via. More particularly, the present invention relates to a method of forming a self-aligned contact via for a magnetic random access memory (MRAM).

2. Description of the Related Art

Magnetic random access memory (MRAM) is a non-volatile, high-density, fast read/write and radiation-resistant memory device. MRAM is widely used in portable electronic products and advanced mobile digital and network communication instruments. To write data into the MRAM, the most common method includes choosing two current lines such as a bit line and a write word line and alternatively selecting the magnetic memory cell to be written. By changing the magnetizing direction of the magnetic material of the free layer, the magnetic resistance also changes.

The magnetic memory cell has a stacked structure having a plurality of magnetic metallic material layers. The stacked structure includes an anti-ferromagnetic conductive layer, a three-layered ferromagnetic/non-magnetic metal/ferromagnetic synthetic anti-ferromagnetic (SAF) pinned layer, a tunneling barrier layer and a ferromagnetic free layer. Through the high or low magnetic resistance when the direction of magnetization of the pinned layer and the free layer are aligned in parallel or anti-parallel, the logic state ‘1’ or ‘0’ is determined.

In the process of manufacturing a conventional magnetic random access memory, the connection between the magnetic memory cell and the bit line is as follows. First, a substrate is provided. Then, a magnetic memory cell is formed over the substrate. Thereafter, a tantalum layer is formed over the substrate to cover the magnetic memory cell and serve as a capping layer. After that, a dielectric layer is deposited over the tantalum layer. An opening is formed in the dielectric layer to expose the tantalum layer above the magnetic memory cell. Then, a metal is deposited into the opening so that the magnetic memory cell and the bit line are electrically connected.

However, as more magnetic random access memory cells are packed together to increase memory storage capacity, the size of each magnetic memory cell correspondingly reduces. The connection between the magnetic memory cell and the bit line is vulnerable to minor offset in the photolithographic and etching process so that a shorting or an opening of the device occurs with higher frequency. In other words, the device is more prone to failure. More specifically, at the current 0.18 μm line width process, the width of the memory cell short axis is about 360 nm and the internal diameter of the opening is about 200 nm. Therefore, the permitted alignment offset is about 80 nm. When the fabrication of the memory advances into the 0.13 μm line width process, the width of the cell axis shrinks to about 280 nm. If the internal diameter of the opening remains unchanged, the permitted alignment offset is reduced to about 40 nm. As the fabrication of the memory further continues to advance so that the fabrication of 90 nm line width is possible, the width of the cell axis shrinks to about 210 nm and the permitted alignment offset is reduced to only 5 nm. Therefore, fabrication of the memory will be very difficult and forming a reliable connection between the magnetic memory cell and the bit line is increasingly difficult.

In U.S. Pat. No. 6,703,676 B2, a magnetic memory device and fabrication method thereof is disclosed. The bit line is directly connected to the magnetic memory device instead of through an opening. Furthermore, in the conventional technique, U.S. Pat. No. 6,812,040 B2 also introduced an electroless plating or immersion plating method for forming a metallic bump layer, which serves as a via connecting the magnetic memory cell with the bit line. However, the fabrication cost of this method is relatively high.

### SUMMARY OF THE INVENTION

Accordingly, at least one objective of the present invention is to provide a method of forming a self-aligned contact via for a magnetic random access memory that can prevent a shorting or opening of the device due to the misalignment of the contact via as a result of increasing the level of device integration.

To achieve these and other advantages and in accordance with the purpose of the invention, as embodied and broadly described herein, the invention provides a method of forming a self-aligned contact via for a magnetic random access memory. A substrate having a plurality of transistors and interconnects formed therein is provided. Then, a first conductive layer, a pinned layer, a tunneling barrier layer, a free layer, a capping layer and a first dielectric layer are sequentially formed over the substrate. A patterned photoresist layer is formed over the first dielectric layer. Thereafter, using the patterned photoresist layer as a mask, a portion of the first dielectric layer and the capping layer are removed to expose the surface of the free layer. The patterned photoresist layer is removed. After that, using the first dielectric layer and the capping layer as a mask, a portion of the pinned layer, the tunneling barrier layer and the free layer are removed to expose the surface of the first conductive layer and form a magnetic random access memory device. Then, a second dielectric layer is formed over the magnetic random access memory device. A planarization process is performed to remove a portion of the second dielectric layer and form a planar surface on the second dielectric layer. The first dielectric layer and a portion of the second dielectric layer are removed. Hence, a self-aligned contact opening that exposes the surface of the capping layer is formed above the magnetic random access memory. After that, conductive material is deposited to form a second conductive layer that fills the self-aligned contact opening.

According to an embodiment of the present invention, the removing rate of the first dielectric layer is greater than or equal to the removing rate of the capping layer.

According to an embodiment of the present invention, the first dielectric layer has a removing rate greater than or equal to the second dielectric layer.

According to an embodiment of the present invention, the planarization process is accomplished by performing a chemical-mechanical polishing process, for example.

According to an embodiment of the present invention, the process of removing the first dielectric layer and a portion of the second dielectric layer to form the self-aligned contact opening includes performing an etching back operation, for example. The etching back operation includes, for example, a dry etching process or a wet etching process.

According to an embodiment of the present invention, the first dielectric layer is fabricated using low-temperature silicon nitride, low-temperature silicon oxide or silicon oxynitride, for example. The first dielectric layer is formed, for example, by performing a chemical vapor deposition process or a physical vapor deposition process.

According to an embodiment of the present invention, the second dielectric layer is fabricated using low-temperature silicon oxide or aluminum oxide, for example. The method of forming the second dielectric layer includes, for example, performing a chemical vapor deposition process or a physical vapor deposition process.

According to an embodiment of the present invention, the capping layer is fabricated using a single layer of tantalum, tantalum nitride, titanium, titanium nitride, ruthenium, tungsten or aluminum oxide or a combination of the foregoing layers, for example.

According to an embodiment of the present invention, the second conductive layer is fabricated using a single layer of aluminum, copper, aluminum-copper alloy, tantalum or tantalum nitride or a combination of the foregoing layers, for example. The method of forming the second conductive layer includes, for example, performing a chemical vapor deposition process, a physical vapor deposition process or an electrochemical deposition process.

The method, according to the present invention, includes forming a first dielectric layer with a high removing rate to serve as a hard mask layer for a subsequent process of forming the magnetic random access memory. Thereafter, the first dielectric layer is removed to form a self-aligned contact opening. Hence, the shorting or opening of the device after forming the contact via due to an increase in the level of device integration may be effectively avoided. Moreover, the present invention only requires a single operation for fabricating the magnetic random access memory without having to go through a series of complicated processes.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1H are schematic cross-sectional views showing the process of forming a self-aligned contact via for a magnetic random access memory according to one embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

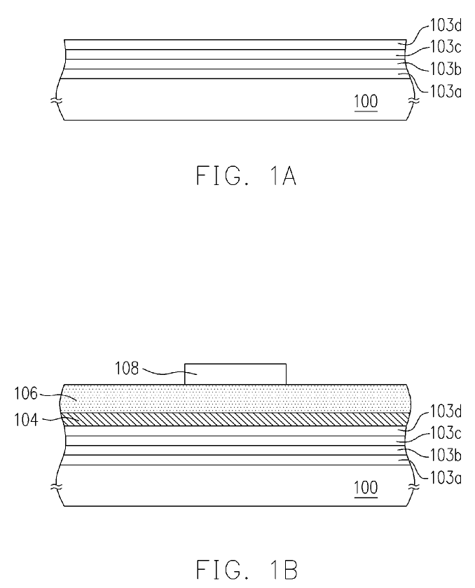

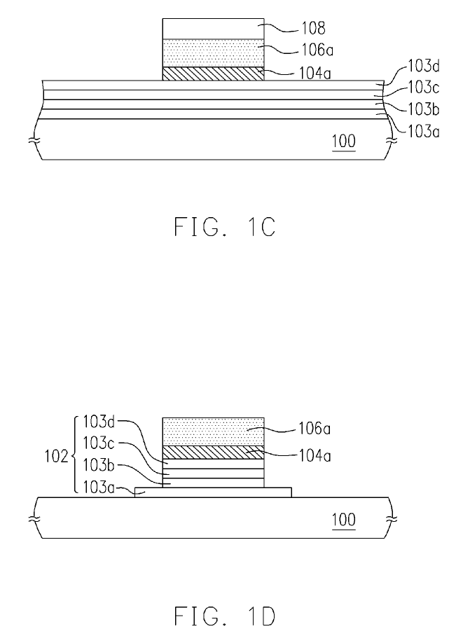

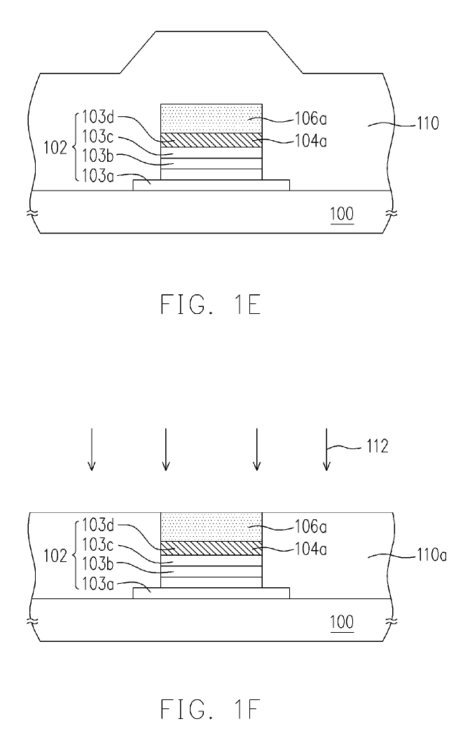

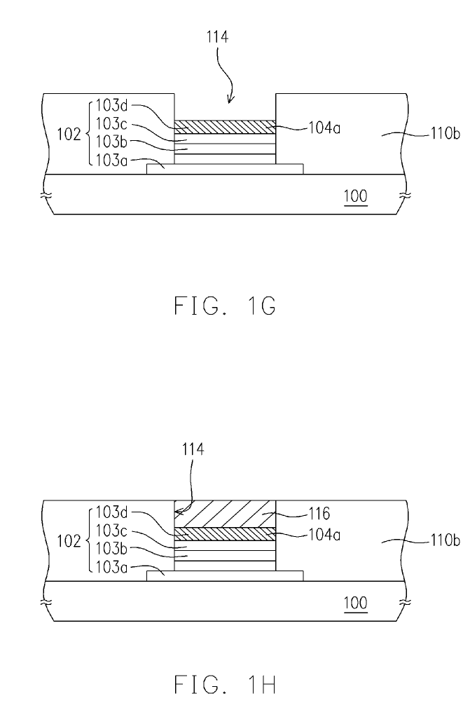

FIGS. 1A through 1H are schematic cross-sectional views showing the process of forming a self-aligned contact via for a magnetic random access memory according to one embodiment of the present invention. As shown in FIG. 1A, a substrate 100 is provided. The substrate 100 has a plurality of transistors and metallic interconnects (not shown) already formed therein. Then, a conductive layer 103a, a pinned layer 103b, a tunneling barrier layer 103c and a free layer 103d are sequentially formed over the substrate 100. The conductive layer 103a serves as a bottom electrode of the magnetic random access memory (MRAM) device. The conductive layer 103a comprises tantalum (Ta), tantalum nitride (TaN), titanium (Ti) or titanium nitride (TiN), for example. The bottom electrode is electrically connected to one of the transistors and metallic interconnects inside the substrate through a contact (not shown). The pinned layer 103b is fabricated using an anti-ferromagnetic layer together with a three-layered synthetic anti-ferromagnetic (SAF) layer. The anti-ferromagnetic layer comprises platinum-manganese (Pt—Mn) alloy or an iridium-manganese (Ir—Mn) alloy and the synthetic anti-ferromagnetic (SAF) layer comprises CoFe/Ru/CoFeB composite layer, for example. The tunneling barrier layer 103c comprises aluminum oxide or magnesium oxide, for example. The free layer 103d can be a single layer or a composite layer comprising NiFe, CoFeB, NiFe/Ru/NiFe or CoFeB/Ru/CoFeB, for example.

As shown in FIG. 1B, a capping layer 104 and a dielectric layer 106 are sequentially formed over the free layer 103d. The capping layer 104 comprises a single layer comprising tantalum, tantalum nitride, titanium, titanium nitride, ruthenium, tungsten or aluminum oxide or a multi-layered composite structure of some of the aforesaid materials. The method of forming the capping layer 104 includes performing a reactive sputtering plating or other suitable deposition process. The dielectric layer 106 is fabricated using low-temperature nitride (LTN), low-temperature silicon oxide (LTO), silicon oxynitride (SiON) or other suitable dielectric materials. The method of forming the dielectric layer 106 includes, for example, performing a chemical vapor deposition (CVD) process or a physical vapor deposition (PVD) process. The chemical vapor deposition process is a plasma-enhanced chemical vapor deposition (PECVD) process, for example. Thereafter, a patterned photoresist layer 108 is formed over the dielectric layer 106.

As shown in FIG. 1C, using the patterned photoresist layer 108 as a mask, a portion of the dielectric layer 106 and the capping layer 104 are removed to expose the surface of the free layer 103d, thereby forming a dielectric layer 106a and a capping layer 104a. The method of using the patterned photoresist layer 108 as a mask to remove a portion of the dielectric layer 106 and the capping layer 104 includes performing an etching operation, for example. The dielectric layer 106a and the capping layer 104a can serve as a hard mask layer in a subsequent step.

In one embodiment, the removing rate of the dielectric layer 106 is greater than or equal to the removing rate of the capping layer 104. When the dielectric layer 106 has a removing rate equal to the capping layer 104, the dielectric layer 106a and the capping layer 104a have a configuration same as the one shown in FIG. 1C. On the other hand, if the dielectric layer 106 has a removing rate greater than the capping layer 104, the bottom width of the dielectric layer 106a will be smaller than the bottom width (not shown) of the capping layer 104a.

As shown in FIG. 1D, the photoresist layer 108 is removed. Then, using the dielectric layer 106a and the capping layer 104a as a mask a portion of the pinned layer 103d, the tunneling barrier layer 103c and the free layer 103b are removed to expose the surface of the conductive layer 103a and form a magnetic random access memory 102. The method of removing a portion of the pinned layer 103d, the tunneling barrier layer 103c and the free layer 103b using the dielectric layer 106a and the capping layer 104a as a mask includes performing an etching operation, for example.

As shown in FIG. 1E, a dielectric layer 110 is formed to cover the magnetic random access memory 102, the capping layer 104a and the dielectric layer 106a. The dielectric layer 110 is fabricated using low-temperature silicon oxide (LTO), aluminum oxide or other suitable dielectric material, for example. The method of forming the dielectric layer 110 includes, for example, performing a chemical vapor deposition process or a physical vapor deposition process. The chemical vapor deposition process is a plasma-enhanced chemical vapor deposition (PECVD) process, for example.

As shown in FIG. 1F, a planarization process 112 is carried out to remove a portion of the dielectric layer 110 and form a dielectric layer 110a. The planarization process 112 is accomplished by performing a chemical-mechanical polishing (CMP) operation, for example.

In one embodiment, the planarization process 112 may remove a portion of the dielectric layer 110 until the surface of the dielectric layer 106a is exposed as shown in FIG. 1F. In another embodiment, the planarization process 112 may remove a portion of the dielectric layer 110 so that a planar surface is formed without exposing the surface of the dielectric layer 106a (not shown).

As shown in FIG. 1G, the dielectric layer 106a and a portion of the dielectric layer 110a are removed so that a self-aligned contact opening 114 that exposes the capping layer 104a is formed above the magnetic random access memory 102. The method of forming the self-aligned contact opening 114 by removing the dielectric layer 106a and a portion of the dielectric layer 110a comprises performing an etching back operation. The etching back operation includes a dry etching process or a wet etching process, for example. In the etching back operation, the removing rate of the dielectric layer 106a is greater than or equal to the removing rate of the dielectric layer 110a.

Because the dielectric layer 106a has a removing rate greater than or equal to the dielectric layer 110a, only a portion of the dielectric layer 110a is removed so that a dielectric layer 110b remains after the dielectric layer 106a is completely removed in the etching back process.

As shown in FIG. 1H, a conductive layer is formed inside the self-aligned contact opening 114 to form a self-aligned contact via. The conductive layer 116 comprises aluminum, copper, aluminum-copper alloy, tantalum, tantalum nitride or other suitable metallic material, for example. The method of depositing the metallic material includes performing a physical vapor deposition process, a chemical vapor deposition process or an electrochemical deposition (ECD) process, for example. Obviously, it is possible to simultaneously form the self-align contact via and a bit line by forming a conductive layer 116 over the substrate 100 to cover the dielectric layer 110b and fill the self-aligned contact opening 114.

Thereafter, processes that need to complete the fabrication such as forming a bit line and a passivation layer are carried out. Since these techniques should be familiar to anyone knowledgeable in semiconductor production, a detailed description is omitted.

In summary, the present invention includes at least the following advantages:

1. The method of the present invention is capable of forming a self-aligned contact via that serves as a connection between a magnetic random access memory and a bit line above that may avoid the shorting or opening problem associated with an increase in the level of device integration.

2. The self-aligned contact via is formed without the need to use the conventional electroless plating or immersion plating method. Hence, the fabrication cost can be substantially reduced.

3. Only a single planarization operation is required to form the self-aligned contact via for the magnetic random access memory. In other words, relatively simple processes are required in the fabrication of the self-aligned contact via according to the present invention.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a self-aligned contact via for a magnetic random access memory, comprising the steps of:
providing a substrate comprising a plurality of transistors and a plurality of metallic interconnects formed therein;
sequentially forming a first conductive layer, a pinned layer, a tunneling barrier layer, a free layer, a capping layer and a first dielectric layer over the substrate;
forming a patterned photoresist layer over the first dielectric layer;
removing a portion of the first dielectric layer and the capping layer using the patterned photoresist layer as a mask to expose the surface of the free layer;
removing the patterned photoresist layer;
removing a portion of the pinned layer, the tunneling barrier layer and the free layer to expose the surface of the first conductive layer and form a magnetic random access memory;
forming a second dielectric layer to cover the magnetic random access memory device;
performing a planarization process to remove a portion of the second dielectric layer;
removing the first dielectric layer and a portion of the second dielectric layer to form a self-aligned contact opening that exposes a surface of the capping layer above the magnetic random access memory; and
depositing a conductive material into the self-aligned contact opening to form a second conductive layer.

2. The method of claim 1, wherein the first dielectric layer has a removing rate greater than or equal to the capping layer.

3. The method of claim 1, wherein the first dielectric layer has a removing rate greater than or equal to the second dielectric layer.

4. The method of claim 1, wherein the planarization process comprises performing a chemical-mechanical polishing operation.

5. The method of claim 1, wherein the step of removing the first dielectric layer and a portion of the second dielectric layer to form the self-aligned contact opening comprises performing an etching back process.

6. The method of claim 1, wherein the etching back process includes a dry etching operation or a wet etching operation.

7. The method of claim 1, wherein a material constituting the first dielectric layer comprises low-temperature silicon nitride, low-temperature silicon oxide or silicon oxynitride.

8. The method of claim 1, wherein the step of forming the first dielectric layer comprises performing a chemical vapor deposition process or a physical vapor deposition process.

9. The method of claim 1, wherein a material constituting the second dielectric layer comprises low-temperature silicon oxide or aluminum oxide.

10. The method of claim 1, wherein the step of forming the second dielectric layer comprises performing a chemical vapor deposition process or a physical vapor deposition process.

11. The method of claim 1, wherein a material constituting the capping layer comprises tantalum, tantalum nitride, titanium, titanium nitride, ruthenium, tungsten or aluminum oxide.

12. The method of claim 1, wherein a material constituting the second conductive layer comprises aluminum, copper, aluminum-copper alloy, tantalum or tantalum nitride.

13. The method of claim 1, wherein the step of forming the second conductive layer comprises performing a chemical vapor deposition process, a physical vapor deposition process or an electrochemical deposition process.
